(19) United States
(12) Patent Application Publication
(10) Pub. No.: US 2026/0047053 A1
(43) Pub. Date: Feb. 12, 2026

(54) POWER MODULE ASSEMBLY

(71) Applicant: SCHNEIDER ELECTRIC IT CORPORATION, Foxboro, MA (US)

(72) Inventors: Rong Long, St. Louis, MO (US); Mario Eduardo Salazar Granados, Round Rock, TX (US)

(21) Appl. No.: 19/294,528

(22) Filed: Aug. 8, 2025

Related U.S. Application Data
(60) Provisional application No. 63/680,885, filed on Aug. 8, 2024.

(51) Int. Cl. H05K 7/20

(52) U.S. Cl. CPC H05K 7/2089

(57) ABSTRACT

A prefabricated power module assembly includes a cooling module, a power module, a cold air interface configured to enable relatively cool air from the cooling module to flow to the power module, a hot air interface configured to enable relatively warm air from the power module to flow to the cooling module, and a cooler in the cooling module. The cooler has an input coupled to the hot air interface and an output coupled to the cold air interface. The cooling module is positioned above the power module.

### CROSS-REFERENCE TO RELATED APPLICATION

This application claims the benefit under 35 U.S.C. § 119 of U.S. Provisional Patent Application Ser. No. 63/680,885, filed Aug. 8, 2024, and titled POWER MODULE ASSEMBLY, which is hereby incorporated herein by reference in its entirety for all purposes.

### BACKGROUND OF THE DISCLOSURE

### 1. Field of Disclosure

The present disclosure is directed to data center architecture, and more particularly to systems and methods used to cool equipment within the data center.

### 2. Discussion of Related Art

With modern power requirements, an increased load density of a new data center is roughly 5-20 kW/rack to 50-200 kW/rack, which means the same square footage of white space fits in 5-10 times kW IT load. To support the IT load, a power module density is also increased 5-10 times. Thus, it is a significant challenge to fit all power modules in the limited space associated with the data hall white space. Traditionally, the power modules require sufficient clearance to install a mechanical cooling system while maintaining minimum clearance to ensure cooling system performance. Presently, power modules are installed in a side-by-side relationship to be able to fit the power modules in a limited site space.

### SUMMARY OF THE DISCLOSURE

One aspect of the present disclosure is directed to a prefabricated power module assembly comprising a cooling module, a power module, a cold air interface configured to enable relatively cool air from the cooling module to flow to the power module, a hot air interface configured to enable relatively warm air from the power module to flow to the cooling module, and a cooler in the cooling module. The cooler has an input coupled to the hot air interface and an output coupled to the cold air interface. The cooling module is positioned above the power module.

Embodiments of the power module assembly further may include a barrier disposed between the cold air interface and the hot air interface. The barrier may be configured to contain relatively warm air delivered to the cooling module from the power module. The barrier may include multiple panels or walls. The cold air interface may include at least one opening formed in the cooling module. The hot air interface may include at least one opening formed in the cooling module. The input may include a damper to control the flow of relatively warm air to the cooler. The output may include a damper to control airflow of relatively cool air to the cold air interface. The power module may include a plurality of heat-generating equipment. The plurality of heat-generating equipment may include uninterruptible power supplies (UPSs), battery cabinets and power distribution units (PDUs). The cooling module may be configured to deliver relatively cool air from above an aisle in front of the heat-generating equipment.

Another aspect of the present disclosure is directed to a cooling module configured to operate with a power module. In one embodiment, the cooling module comprises a cold air interface configured to enable relatively cool air from the cooling module to flow to the power module, a hot air interface configured to enable relatively warm air from the power module to flow to the cooling module, and a cooler including an input coupled to the hot air interface and an output coupled to the cold air interface. The cooling module is configured to be positioned above the power module.

Embodiments of the cooling module further may include configuring the cold air interface with at least one opening formed in the cooling module. The hot air interface may include at least one opening formed in the cooling module. The input may include a damper to control airflow of relatively warm air to the cooler. The output may include a damper to control airflow of relatively cool air to the cold air interface. The cooling module may be configured to deliver relatively cool air from above an aisle in front of heat-generating equipment of the power module.

Yet another aspect of the present disclosure is directed to a method of cooling heat-generating equipment in a power module. In one embodiment, the method comprises: delivering relatively cool air from a cooling module to the power module through a cold air interface; and delivering relatively warm air from the power module to the cooling module through a hot air interface. The cooling module includes a cooler having an input coupled to the hot air interface and an output coupled to the cold air interface. The cooling module is positioned above the power module.

Embodiments of the method further may include separating spaces between the cold air interface and the hot air interface with a barrier. The barrier may be configured to contain relatively warm air delivered to the cooling module from the power module. The barrier may include multiple panels or walls. The cold air interface may include at least one opening formed in the cooling module. The hot air interface may include at least one opening formed in the cooling module. The input may include a damper to control airflow of relatively warm air to the cooler. The output may include a damper to control airflow of relatively cool air to the cold air interface.

### BRIEF DESCRIPTION OF THE DRAWINGS

The accompanying drawings are not intended to be drawn to scale. In the drawings, each identical or nearly identical component that is illustrated with various figures, are represented by a line numeral. For purposes of clarity, not every component may be labeled in every drawing. In the drawings:

FIG. 1 is a perspective view of a prefabricated power module assembly including a power module and a top cooling module of an embodiment of the present disclosure;

FIG. 2 is a top view of an exemplary data center site layout;

FIG. 3 is a top view of several top cooling modules disposed over power modules;

FIG. 4 is a cross-sectional end view of the power module assembly including the power module and the top cooling module;

FIG. 5 is a top view of the prefabricated power module assembly showing the power module and the top cooling module in side-by-side relation to one another;

FIG. 6 is a top view of the prefabricated power module assembly showing the power module and the top cooling module overlapping with one another;

FIG. 7 is a back view of the prefabricated power module assembly illustrating flow of relatively warm air through the assembly;

FIG. 8 is a back view of the prefabricated power module assembly;

FIG. 9 is a perspective view of the prefabricated power module assembly showing manually adjustable louvres;

FIG. 10 is a cross-sectional end view of the power module assembly including the power module and the top cooling module, illustrating supply and return airflow through the assembly; and

FIG. 11 is a top view of the power module assembly having a different UPS system.

### DETAILED DESCRIPTION OF THE DISCLOSURE

Embodiments of the present disclosure are directed to a prefabricated power module assembly, which is configured to utilize the elevational space above a power module to support a top cooling module that is placed on top of the power module, since the square footage around the power module is limited. As is known, relatively warm or hot air will naturally rise from the heat dissipation equipment contained in the power module, such as an uninterruptible power supply (UPS). The UPSs provided in the power module have top air exhaust, which is configured to direct relatively warm air to the top of the power module. The relatively warm air is easily captured by coolers, sometimes referred to as cooling units, which are provided in the top cooling module. Once the relatively warm air is cooled by the coolers of the top cooling module, the relatively cool air is sent back to the power module.

The top cooling module takes advantage of the space above the power module to support mechanical equipment associated with the top cooling module, thereby enabling the installation of the power modules side-by-side with one another. The top cooling module further utilizes thermal science technology to optimize airflow management within its respective power module. Additionally, the modular design enables layout flexibility to customers.

Embodiments of the present disclosure are not limited in their application to the details of construction and the arrangement of components set forth in the following descriptions or illustrated by the drawings. The disclosure is capable of other embodiments and of being practiced or of being carried out in various ways. Also, the phraseology and terminology used herein is for description purposes and should not be regarded as limiting. The use of “including,” “comprising,” “having,” “containing,” “involving,” and variations herein, are meant to be open-ended, i.e., “including but not limited to.”

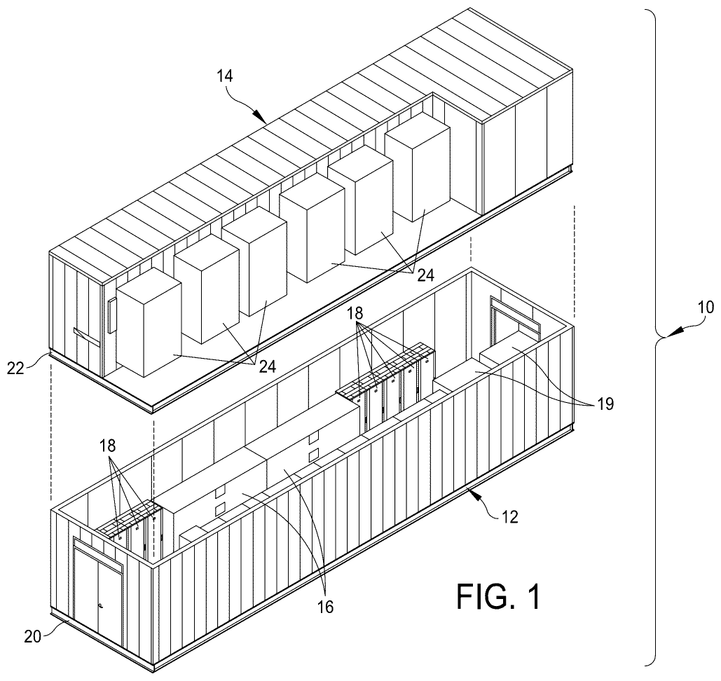

Referring to FIG. 1, a prefabricated power module assembly, generally indicated at 10, includes a power module 12 and a prefabricated top cooling module 14, which is positioned on top of the power module. The power module 12 includes power equipment including UPSs, each indicated at 16, battery cabinets, each indicated at 18, and power distribution units (PDUs), each indicated at 19, and related equipment, such as batteries and switchgear. In one embodiment, the power module 12 includes a cuboid-shaped power module enclosure 20 having a bottom wall, an optional top wall that is removed from FIG. 1 to view the interior of the enclosure 20, two longer side walls, and two relatively shorter end walls. In one embodiment, the enclosure 20 is shaped and sized to fit the needs of the data center.

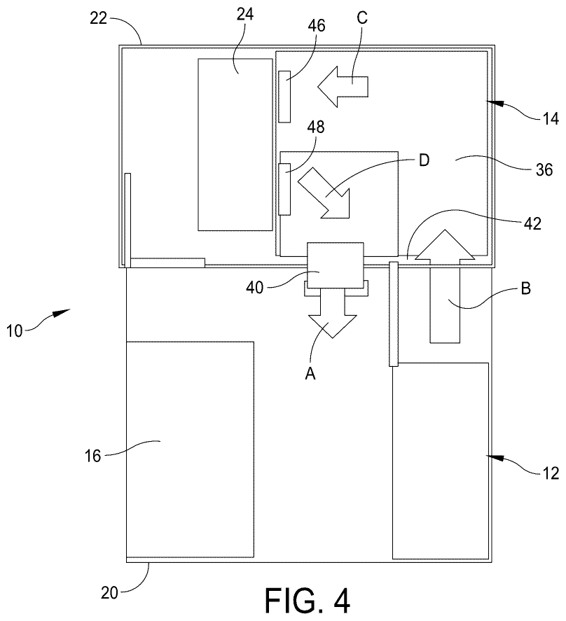

The top cooling module 14 is configured to cool the power equipment provided within the power module 12, where the top cooling module 14 is positioned above the power module 12. The top cooling module 14 includes a cuboid-shaped cooling module enclosure having a bottom wall, a top wall, two longer side walls, and two relatively shorter end walls. As shown, the cooling module enclosure 22 include cooling units, each indicated at 24, which are either wall mounted or supported by the bottom wall of the top cooling module enclosure to provide cooling for the power module 12. As with the power module 12, in one embodiment, the top cooling module enclosure 22 of the top cooling module 14 has the form factor of the power module enclosure 20 of the power module 12 and is configured to be placed on top of the power module 12. As described in greater detail below with reference to FIG. 4, the prefabricated power module assembly 10 has cold air and hot air interfaces between the top cooling module 14 and the power module 12, with the cold air and hot air and further being separated by a barrier.

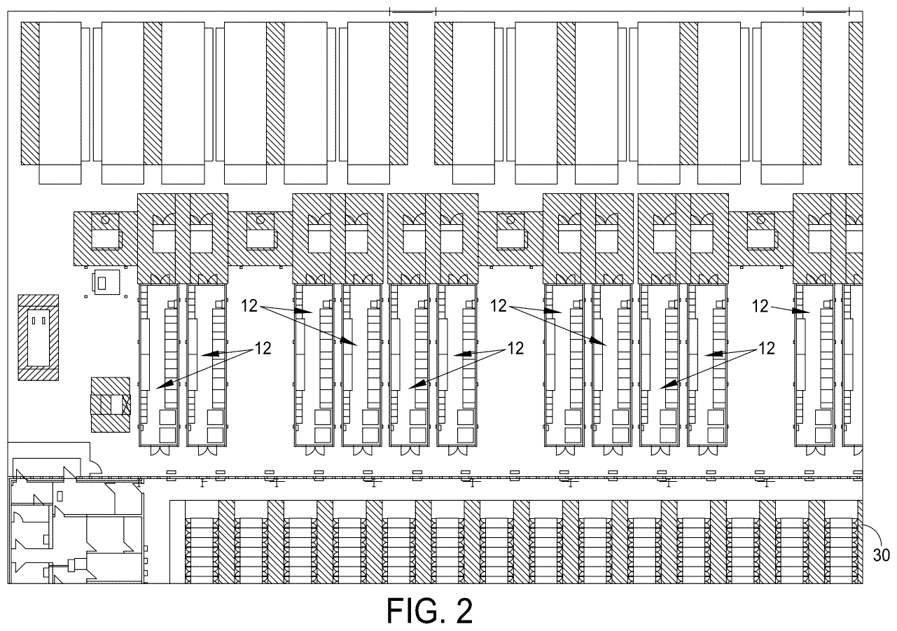

Referring to FIG. 2, an exemplary site layout is illustrated. A data center 30 is shown to be supported by high-density power modules 12, which are positioned outside the data center 30. As shown, the power modules 12 are spaced close to one another, with very little room between adjacent power modules 12. As noted, the space above each power module 12 enables the top cooling module 14 (not shown) to be positioned on top its respective power module 12 to cool the power equipment provided in the power module 12. In the shown embodiment, the power modules 12 are placed outside the data center 30 in a position in which the power modules 12 are perpendicular to an outside wall of the data center 30. The power modules 12 are configured to be connected to the data center 30 by power cables, communication cables and other suitable equipment to provide power and associated communication to the data center 30. As noted, but not shown in FIG. 2, the top cooling modules 14 are configured to be positioned on top of the power modules 12 to provide dedicated cooling to their respective power modules 12. As noted herein, other layouts are contemplated.

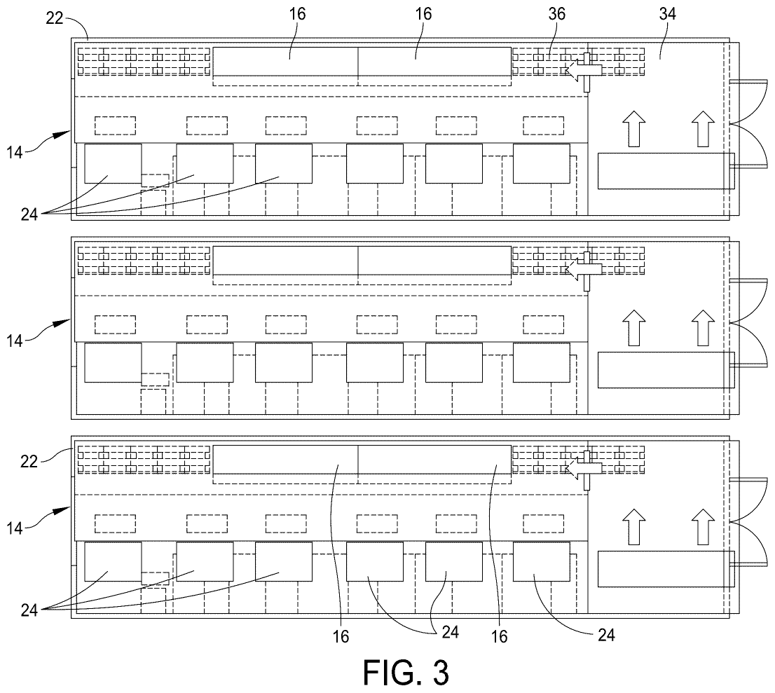

Referring to FIG. 3, the top cooling modules 14 are shown positioned over their respective power modules 12. As shown, relatively warm air generated by the PDUs 19 is directed from the space 34 along a horizontal plenum 36, sometimes referred to as a return air plenum, where the relatively warm air is delivered to the cooling units 24, provided within the top cooling module 14. Similarly, the relatively warm air generated by the UPSs 16 is directed to the horizontal plenum 36 where the relatively warm air is combined with the relatively warm air from the PDUs 19 is delivered to the cooling units 24. Cool air generated by the cooling units 24 is delivered back to the power units through the interfaces described below with reference to FIG. 4. As shown, an opening is disposed above an aisle in front of the UPSs 16, which may function as an interface. Other smaller openings may be provided below opening, which also function as interfaces. Although a one foot (1 ft) distance between adjacent top cooling modules 14 is illustrated in FIG. 3, it should be understood that the power module assemblies 10 including the top cooling modules 14 can be spaced further apart from one another, e.g., three feet (3 ft) to provide for easier installation.

Referring to FIG. 4, in one embodiment, the present disclosure is directed to the prefabricated power module assembly 10. As shown, the power module assembly 10 includes the power module, which may be referred to as a power equipment module, and the top cooling module 14, which is configured to provide dedicated cooling to the power module 12. As noted above, the power module 12 includes power equipment, including the UPSs 16, battery cabinets 18 and PDUs 19, and related equipment supported by the power module enclosure 20. The top cooling module enclosure 22 of the top cooling module 14 is configured to be positioned on top of the power module enclosure 20 of the power module 12 to provide dedicated cooling to the power equipment, e.g., UPS 16, contained within the power module 12.

The prefabricated power module assembly 10 further includes a cold air interface 40, which is located between the top cooling module 14 and the power module 12. In one embodiment, the cold air interface 40 is installed prior to when the cooling module enclosure 22 of the top cooling module 14 is secured on top of the power module enclosure 20 the power module 12. In one example, aligned openings are formed in the top wall of the power module enclosure 20 of the power module 12 and the bottom wall of the top cooling module enclosure 22 of the top cooling module 14 to create the cold air interface 40. In another example, the power module enclosure 20 of the power module 12 does not include a top wall, with an opening being formed in the bottom wall of the top cooling module enclosure 22 of the top cooling module 14 only. Arrow A shows relatively cool air generated by the cooling unit 24 within the top cooling module 14 traveling through the cold air interface 40 to an open space provided in the power module 12 adjacent the UPS 16. In one embodiment, the open space may be an aisle in front of the UPS 16.

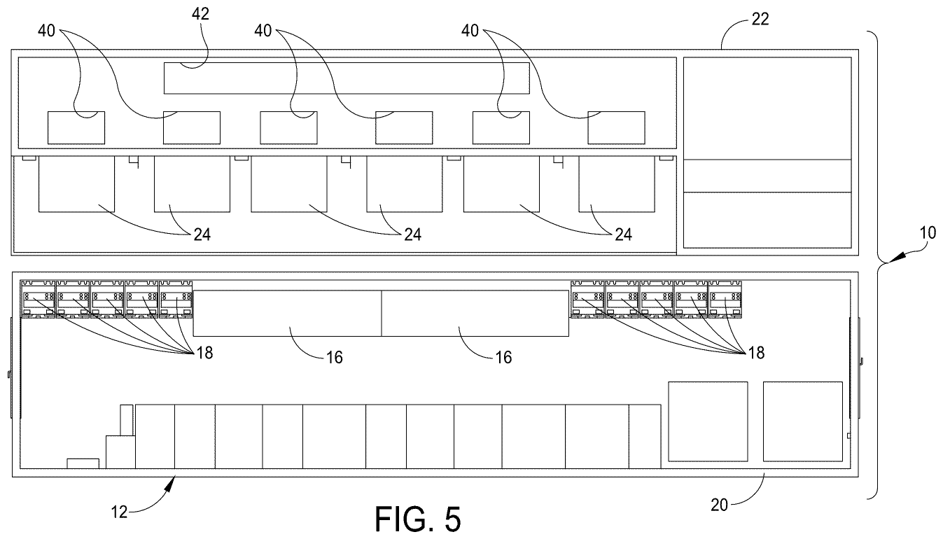

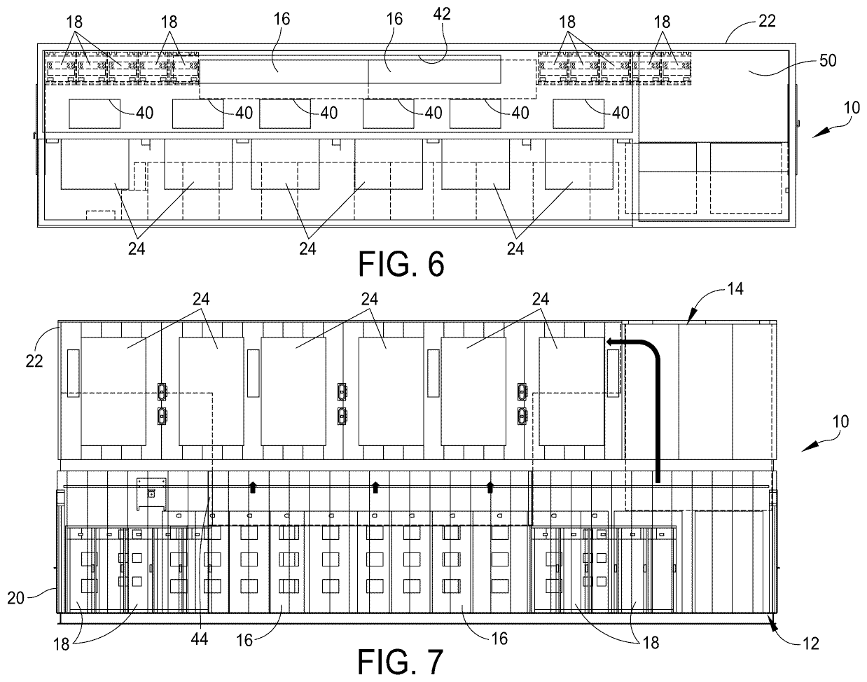

The cold air interface 40 may be configured to include a diffuser. The diffuser may be any suitable device that is configured to distribute conditioned air into the space of the interior of the power module 12, ensuring even airflow and temperature distribution. In another embodiment, the cold air interface 40 may be configured to include a damper, which may be configured to move from a normally open position in which cold air is delivered from the top cooling module 14 to the power module 12 and a closed position in which cold air is prevented from flowing to the power module 12. The power module 12 and the top cooling module 14 can be configured to include more than one cold air interface 40. For example, FIGS. 5 and 6 illustrate six cold air interfaces 40, one for each cooling unit 24.

The power module assembly 10 further includes a hot air interface 42, which is located between the top cooling module 14 and the power module 12. As with the cold air interface 40, in one embodiment, the hot air interface 42 is installed or otherwise created prior to when the cooling module enclosure 22 of the top cooling module 14 is secured on top of the power module enclosure 20 of the power module 12. In one example, aligned openings are formed in the top wall of the power module enclosure 20 of the power module 12 and the bottom wall of the top cooling module enclosure 22 of the top cooling module 14 to create the hot air interface 42. In another example, the power module enclosure 20 of the power module 12 does not include a top wall, with openings being formed in the bottom wall of the top cooling module enclosure 22 of the top cooling module 14 only. Arrow B shows relatively warm air generated by the power equipment within the power module 12 traveling through the hot air interface to an open space provided in the top cooling module 14. The hot air interface may include perforated panels or grills to enable the relatively warm air to travel from the power module 12 to the top cooling module 14. In one embodiment, as shown in FIGS. 5 and 6, a single hot air interface 42 is provided.

To prevent the relatively cool air delivered from the top cooling module 14 to the power module 12 via the cold air interface 40 from mixing with the relatively warm air within an air containment area within the power module 12, a barrier 44 is disposed between the cold air interface 40 and the hot air interface 42. As shown, the barrier 44 extends vertically between the cold air interface 40 and the hot air interface 42. In one embodiment, the barrier 44 embodies a solid structure, such as a vertical wall or panel. The barrier 44 is positioned to ensure that relatively cool air delivered to the power module 12 from the top cooling module 14 is directed toward the heat-generating equipment, e.g., the UPSs 16, supported by the power module 12, and prevented from mixing with the relatively warm air.

As noted above, the top cooling module 14 may include multiple cooling units, e.g., six cooling units 14, to provide dedicated cooling to the power module 12. The cooling units are configured to cool warm air and deliver cool air. In one embodiment, each cooling unit can embody traditional refrigeration cycle cooling units. In another embodiment, each cooling unit can be connected to a chiller unit. In another embodiment, each cooling unit can embody a direct or indirect air economizer unit.

As shown, the cooling unit 24 has an input 46, which is coupled to the hot air interface 42 to deliver the relatively warm air from the power module 12 to the cooling unit. Arrow C shows relatively warm air from the power module 12 traveling from the hot air interface 42 to the input 46 of the cooling unit 24. The cooling unit 24 further includes an output 48, which is coupled to the cold air interface 40 to deliver relatively cool air from the cooling unit 24 to the cold air interface 40. Arrow D shows relatively cool air from the cooling module 14 traveling out of the output 48 to the cold air interface 40. A duct may be provided to facilitate this transfer of relatively cool air. As shown and noted above, the top cooling module 14 is configured to be positioned above the power module 12.

In another embodiment, each of the input 46 and the output 48 may be configured to include a damper, which may be configured to move from an open position to enable airflow and a closed position to inhibit airflow. As described above, the damper for the output 48 may be positioned at the cold air interface.

In some embodiments, the damper for each of the cold air interface 40, the input 46 and the output 48 may embody any device that enables or otherwise control the flow of air within the power module assembly 10. The dampers are part of a fire suppression gas system in which the damper is always in a fully open position to allow air to pass therethrough. When smoke or fire is detected, the damper closes to a fully closed position before any gas is released to hold the required pressure and time so that the cause of the smoke or fire is addressed.

Referring to FIGS. 5 and 6, the top cooling module 14 is positioned on top of the power module 12. As noted above in the description of FIG. 4, relatively warm air generated by the power equipment in the power module 12 is delivered to the top cooling module 14 by hot air interface 42, which is configured to treat the air and return relatively cool air to the power module 12. Specifically, the cooling units 24 of the top cooling module 14 are positioned next to respective cold air interfaces 40 to deliver relatively cool air to the power module 12. As shown, there are six smaller cold air interfaces 40 to provide relatively cool air to the power module enclosure 20. The hot air interface 42 is shown to be adjacent to the cold air interfaces 40 through which relatively warm air is returned to the top cooling module 14.

Referring to FIG. 7, relatively warm air generated by the power equipment in the power module 12 is directed upwards within the power module 12 towards the top cooling module 14. The relatively warm air is then directed along one or more horizontal plenums, each indicated at 50, where the relatively warm air is delivered to cooling units 24 disposed within the top cooling module 14. FIG. 7 shows two barriers 44 provided to help ensure that the relatively cool air delivered to the power module 12 from the top cooling module 14 does not mix with the relatively warm air that is directed back to the top cooling module 14. A third barrier (not shown) is provided in front of the UPSs 16. All three barriers 44 extend from a top of the UPSs 16 to a bottom of the cooling module 14.

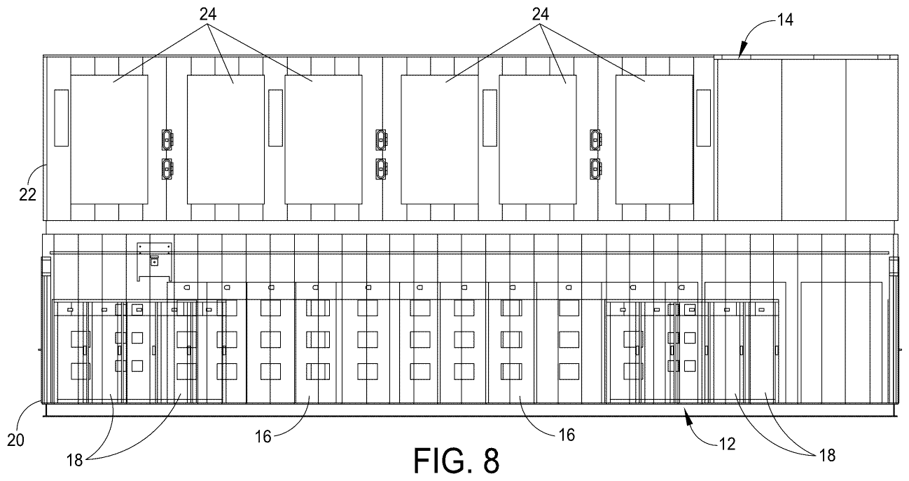

Referring to FIG. 8, relatively cool air generated by the cooling units 24 of the top cooling module 14 is directed to the power module 12 to cool the power equipment supported by the power module 12. As noted above, the relatively cool air passes through the cold air interfaces 40 provided between the top cooling module 14 and the power module 12.

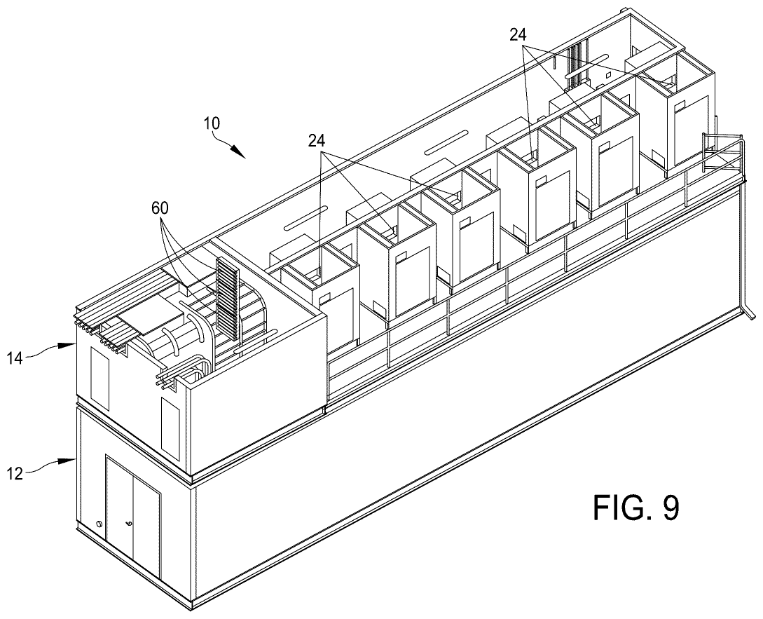

Referring to FIG. 9, in one embodiment, airflow through the prefabricated power module assembly 10, and especially through the PDU area of the power module 12, can be controlled by several manually adjustable louvers, each indicated at 60, provided in the top cooling module 14. As shown, each manually adjustable louver 60 is configured to be manually adjusted to adjust an opening percentage of airflow. Each manually adjustable louver 60 may embody a motorized damper to automatically control a percentage of the opening.

In another embodiment, airflow can naturally occur without the provision of the adjustable louvers 60.

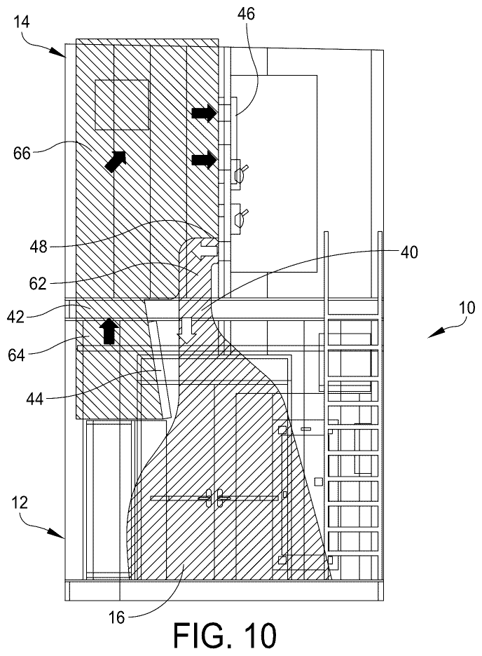

Referring to FIG. 10, in one embodiment, the size and scope of the top cooling module 14 and the power module 12 are illustrated. The flow of relatively warm air and the flow of relatively cool air is illustrated as well. As shown, the barrier 44 separates the relatively warm air from the relatively cool air. Further, the delivery of relatively warm air to the cooling unit 24 is controlled by the input 46 and the delivery of relatively cool air to the power module 12 is controlled by the output 48. As shown, the cooling unit 24 of the top cooling module 14 is configured to produce cool air, which is delivered through the output 48 to a duct 62 to the cold air interface 40. The relatively cool air is directed to the power equipment, e.g., UPS 16, of the power module 12. Heat produced by the power equipment warms the relatively cool air. The relatively warm air is delivered back to the cooling unit 24 of the top cooling module 14 through a containment area 64 created by barrier 44 to the hot air interface 42. The relatively warm air then travels through a return air plenum 66 and directed to the cooling unit 24 through the input 46 where the air is conditioned for return to the power module 12.

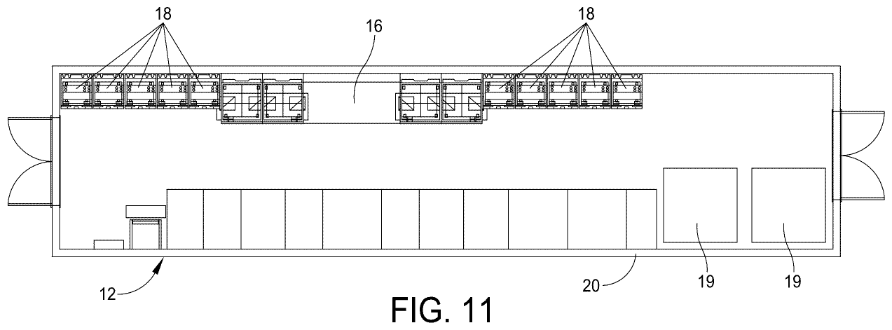

Referring to FIG. 11, a site layout of the power module 12 of another embodiment is shown. As shown, the power module 12 includes the UPS 16 having an alternative or different arrangement within the power module 12. The UPS 16 includes an air exhaust located at the back of the UPS 16. As shown, the UPS 16 is spaced from an adjacent side wall of the power module enclosure 20 of the power module 12. The top cooling module, e.g., top cooling module 14 can be configured to accommodate the power module 12 having the UPS 16. Specifically, the top cooling module and the power module 12 can be configured to direct relatively cool air to a cold air interface that is positioned behind the UPS 16.

One aspect of the present disclosure is directed to a method of cooling heat-generating equipment, e.g., UPSs 16, battery cabinets 18 and PDUs 19, in the power module 12. In one embodiment, the method includes delivering relatively cool air from the top cooling module 14 to the power module 12 through the cold air interface 40 and delivering relatively warm air from the power module 12 to the top cooling module 14 through a hot air interface 42. Relatively cool air from the top cooling unit 24 of the top cooling module 14 is directed to the output 48, which is coupled to the hot air interface 42. Relatively warm air from the power module 12 is directed to the input 46, which is coupled to the cold air interface 40. As noted above, the cooling module 14 is positioned above the power module 12. The method further may include separating spaces between the cold air interface 40 and the hot air interface 42 with the barrier 44.

As noted, the data center heat load density is dramatically increased with AI industry and liquid cooling applications. The power module load density is also dramatically increased, as is the mechanical cooling system provided to support the electrical load. The top cooling module of embodiments of the present disclosure is configured to address these needs. The top cooling module is positioned on top of the power module, with the top cooling module being configured to integrate all N+1, N+2 or 2N coolers, supply air duct/plenum, return air plenum/duct, and other necessary accessories, which will be prefabricated in a prefab factory, tested and verified, and then shipped to customer site for final installation. Thus, the top cooling module is capable of quick deployment or replacement.

In residential/commercial applications, there is roof top air conditioner (AC) unit, which is directly mounted on the roof. In power module application, it has much higher heat load kW in a small enclosure and requires good airflow management. Aspects of the present disclosure is to integrate coolers in the prefabricated top cooling module, which will house all coolers plus airflow management plenum/duct. The top cooling module is mounted on top of the power module, which takes zero white space, and is able to fit in the limited site space. The cooling module plenum/duct will optimize the airflow management to effectively capture hot air/heat load in the power module.

Aspects of the present disclosure can also be applied to modular data centers. Modular data centers are portable data centers capable of deploying data center capacity anywhere data capacity is needed. Modular data center systems consist of purpose-engineered modules and components to offer scalable data center capacity with multiple power and cooling options. As with the power module and the top cooling module, the modular data center can be contained within a suitable enclosure, which can be shipped to be added, integrated or retrofitted into an existing data center or combined into a system of modules. In one example, the modular data center can be employed with the top cooling module positioned above the modular data center to provide dedicated cooling.

The top cooling module 14 can be configured to be operated under the control of a controller, which may be a dedicated controller for the top cooling module 14 or a controller associated with the power module 12. Various controllers may execute cooling functions discussed herein. Using data stored in associated memory and/or storage, the controllers may also execute one or more instructions stored on one or more non-transitory computer-readable media that may result in manipulated data. In some examples, the controllers may include one or more processors or other types of controllers. In one example, the controllers are or include a commercially available, general-purpose processor. In another example, the controllers perform at least a portion of the operations discussed above using an application-specific integrated circuit tailored to perform particular operations in addition to, or in lieu of, a general-purpose processor. As illustrated by these examples, examples in accordance with the present invention may perform the operations described herein using many specific combinations of hardware and software and the invention is not limited to any particular combination of hardware and software components.

Further embodiments are described below.

Clause 1. A prefabricated power module assembly (10), comprising:
a cooling module (14);
a power module (12);
a cold air interface (40) configured to enable relatively cool air from the cooling module (14) to flow to the power module (12);
a hot air interface (42) configured to enable relatively warm air from the power module (12) to flow to the cooling module (14); and
a cooler (24) in the cooling module (14), the cooler (24) having an input (46) coupled to the hot air interface (42) and an output (48) coupled to the cold air interface (40),
wherein the cooling module (14) is positioned above the power module (12).

Clause 2. The assembly (10) of clause 1, further comprising a barrier (44) disposed between the cold air interface (40) and the hot air interface (42).

Clause 3. The assembly (10) of clause 2, wherein the barrier (44) is configured to contain relatively warm air delivered to the cooling module (14) from the power module (12).

Clause 4. The assembly (10) of clauses 2 or 3, wherein the barrier (44) includes multiple panels or walls.

Clause 5. The assembly (10) of any of clauses 1-4, wherein the cold air interface (40) includes at least one opening formed in the cooling module (14).

Clause 6. The assembly (10) of any of clauses 1-5, wherein the hot air interface (42) includes at least one opening formed in the cooling module (14).

Clause 7. The assembly (10) of any of clauses 1-6, wherein the input (46) includes a damper to control the flow of relatively warm air to the cooler (24).

Clause 8. The assembly (10) of any of clauses 1-7, wherein the output (48) includes a damper to control airflow of relatively cool air to the cold air interface (40).

Clause 9. The assembly (10) of any of clauses 1-8, wherein the power module (12) includes a plurality of heat-generating equipment (16, 18, 19).

Clause 10. The assembly (10) of clause 9, wherein the plurality of heat-generating equipment (16, 18, 19) includes uninterruptible power supplies (16), battery cabinets (18) and power distribution units (19).

Clause 11. The assembly (10) of clauses 9 or 10, wherein the cooling module (14) is configured to deliver relatively cool air from above an aisle in front of the heat-generating equipment (16, 18, 19).

Clause 12. A cooling module (14) configured to operate with a power module (12), the cooling module (14) comprising:
a cold air interface (40) configured to enable relatively cool air from the cooling module (14) to flow to the power module (12);
a hot air interface (42) configured to enable relatively warm air from the power module (12) to flow to the cooling module (14); and
a cooler (24) including an input (46) coupled to the hot air interface (42) and an output (48) coupled to the cold air interface (40),
wherein the cooling module (14) is configured to be positioned above the power module (12).

Clause 13. The cooling module (14) of clause 12, wherein the cold air interface (40) includes at least one opening formed in the cooling module (14).

Clause 14. The cooling module (14) of clauses 12 or 13, wherein the hot air interface (42) includes at least one opening formed in the cooling module (14).

Clause 15. The cooling module (14) of any of clauses 12-14, wherein the input (46) includes a damper to control airflow of relatively warm air to the cooler (24).

Clause 16. The cooling module (14) of any of clauses 12-15, wherein the output 48 includes a damper to control airflow of relatively cool air to the cold air interface 40.

Clause 17. The cooling module (14) of any of clauses 12-16, wherein the cooling module 14 is configured to deliver relatively cool air from above an aisle in front of heat-generating equipment 16, 18, 19 of the power module 12.

Clause 18. A method of cooling heat-generating equipment (16, 18, 19) in a power module (12), the method comprising:
delivering relatively cool air from a cooling module (14) to the power module (12) through a cold air interface (40); and
delivering relatively warm air from the power module (12) to the cooling module (14) through a hot air interface (42),
wherein the cooling module (14) includes a cooler (24) having an input (46) coupled to the hot air interface (42) and an output (48) coupled to the cold air interface (40), and
wherein the cooling module (14) is positioned above the power module (12).

Clause 19. The method of clause 18, further comprising separating spaces between the cold air interface (40) and the hot air interface (42) with a barrier (44).

Clause 20. The method of clause 18, wherein the barrier (44) is configured to contain relatively warm air delivered to the cooling module (14) from the power module (12).

Clause 21. The method of clauses 18 or 19, wherein the barrier (44) includes multiple panels or walls.

Clause 22. The method of any of clauses 18-21, wherein the cold air interface (40) includes at least one opening formed in the cooling module (14).

Clause 23. The method of any of clauses 18-22, wherein the hot air interface (42) includes at least one opening formed in the cooling module (14).

Clause 24. The method of any of clauses 18-23, wherein the input (46) includes a damper to control airflow of relatively warm air to the cooler (24).

Clause 25. The method of any of clauses 18-24, wherein the output (48) includes a damper to control airflow of relatively cool air to the cold air interface (40).

Having thus described several aspects of at least one embodiment, it is to be appreciated various alterations, modifications, and improvements will readily occur to those skilled in the art. Such alterations, modifications, and improvements are intended to be part of this disclosure and are intended to be within the scope of the disclosure. Accordingly, the foregoing description and drawings are by way of example only.

1. A prefabricated power module assembly, comprising:
a cooling module;
a power module;
a cold air interface configured to enable relatively cool air from the cooling module to flow to the power module;
a hot air interface configured to enable relatively warm air from the power module to flow to the cooling module; and
a cooler in the cooling module, the cooler having an input coupled to the hot air interface and an output coupled to the cold air interface,
wherein the cooling module is positioned above the power module.

2. The assembly of claim 1, further comprising a barrier disposed between the cold air interface and the hot air interface.

3. The assembly of claim 2, wherein the barrier is configured to contain relatively warm air delivered to the cooling module from the power module.

4. The assembly of claim 2, wherein the barrier includes multiple panels or walls.

5. The assembly of claim 1, wherein the cold air interface includes at least one opening formed in the cooling module.

6. The assembly of claim 1, wherein the hot air interface includes at least one opening formed in the cooling module.

7. The assembly of claim 1, wherein the input includes a damper to control the flow of relatively warm air to the cooler.

8. The assembly of claim 1, wherein the output includes a damper to control airflow of relatively cool air to the cold air interface.

9. The assembly of claim 1, wherein the power module includes a plurality of heat-generating equipment.

10. The assembly of claim 9, wherein the plurality of heat-generating equipment includes uninterruptible power supplies (UPSs), battery cabinets and power distribution units (PDUs).

11. The assembly of claim 9, wherein the cooling module is configured to deliver relatively cool air from above an aisle in front of the heat-generating equipment.

12. A cooling module configured to operate with a power module, the cooling module comprising:
a cold air interface configured to enable relatively cool air from the cooling module to flow to the power module;
a hot air interface configured to enable relatively warm air from the power module to flow to the cooling module; and
a cooler including an input coupled to the hot air interface and an output coupled to the cold air interface,
wherein the cooling module is configured to be positioned above the power module.

13. The cooling module of claim 12, wherein the cold air interface includes at least one opening formed in the cooling module.

14. The cooling module of claim 12, wherein the hot air interface includes at least one opening formed in the cooling module.

15. The cooling module of claim 12, wherein the input includes a damper to control airflow of relatively warm air to the cooler.

16. The cooling module of claim 12, wherein the output includes a damper to control airflow of relatively cool air to the cold air interface.

17. The cooling module of claim 12, wherein the cooling module is configured to deliver relatively cool air from above an aisle in front of heat-generating equipment of the power module.

18. A method of cooling heat-generating equipment in a power module, the method comprising:
delivering relatively cool air from a cooling module to the power module through a cold air interface; and
delivering relatively warm air from the power module to the cooling module through a hot air interface,
wherein the cooling module includes a cooler having an input coupled to the hot air interface and an output coupled to the cold air interface, and
wherein the cooling module is positioned above the power module.

19. The method of claim 18, further comprising separating spaces between the cold air interface and the hot air interface with a barrier.

20. The method of claim 18, wherein the cold air interface includes at least one opening formed in the cooling module and the hot air interface includes at least one opening formed in the cooling module.
